(19) United States
(12) Patent Application Publication
(10) Pub. No.: US 2014/0313687 A1
(43) Pub. Date: Oct. 23, 2014

(54) PRINTED CIRCUIT BOARD ASSEMBLY

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: YU-HSU LIN, Santa Clara, CA (US); GUANG-FENG OU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/093,119

(22) Filed: Nov. 29, 2013

(30) Foreign Application Priority Data
Apr. 18, 2013 (CN) 201310135310X

(51) Int. Cl. H05K 9/00

(52) U.S. Cl. CPC H05K 9/0007
USPC 361/816

(57) ABSTRACT

A printed circuit board assembly comprises a PCB and a shielding structure. The PCB comprises a top surface, a bottom surface, a first side surface, a second side surface, a third side surface, and a fourth side surface. A signal transmission line is laid in the top surface. The shielding structure is attached to the PCB and securely contacts the first side surface, the second side surface, the third side surface, and the fourth side surface. Edges of the top surface and the bottom surface are configured to shield EMI in the signal transmission line when transmitting high-speed differential signals.

### BACKGROUND

1. Technical Field

The present disclosure relates to printed circuit board assemblies, and more particularly to a printed circuit board assembly with a shielding structure.

2. Description of Related Art

Printed circuit boards (PCBs) are designed for coupling control chips to electronic devices. Signal transmission lines are laid on the PCB to transmit signals, such as high-speed differential signals. However, some of the signal transmission lines are required to be laid adjacent to side edges of the PCB. High-speed differential signals of the signal transmission lines generate EMI, which causes an edge effect in the signal transmission lines and causes digital system failure due to false signals appearing on a receiver.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a first embodiment of a printed circuit board.

FIG. 2 is an assembled view of the printed circuit board of FIG. 1.

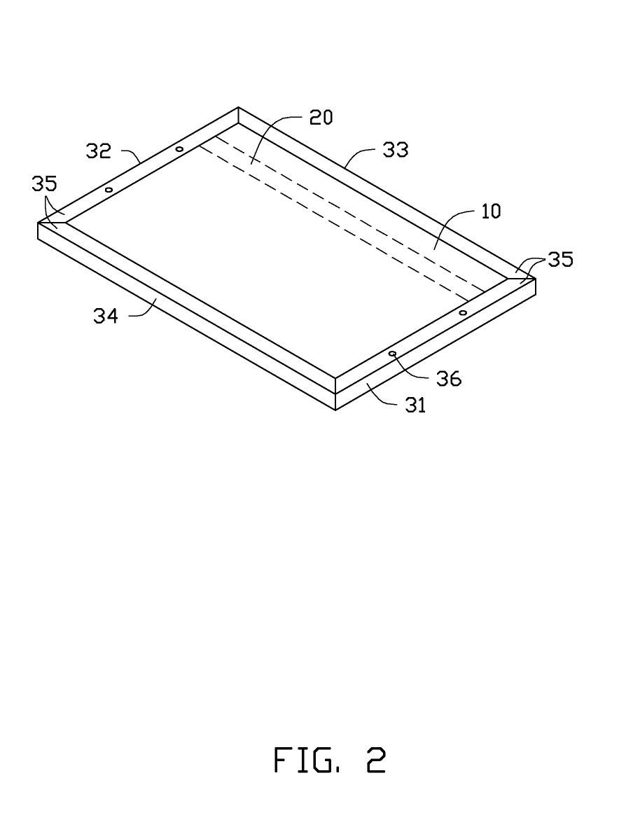

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

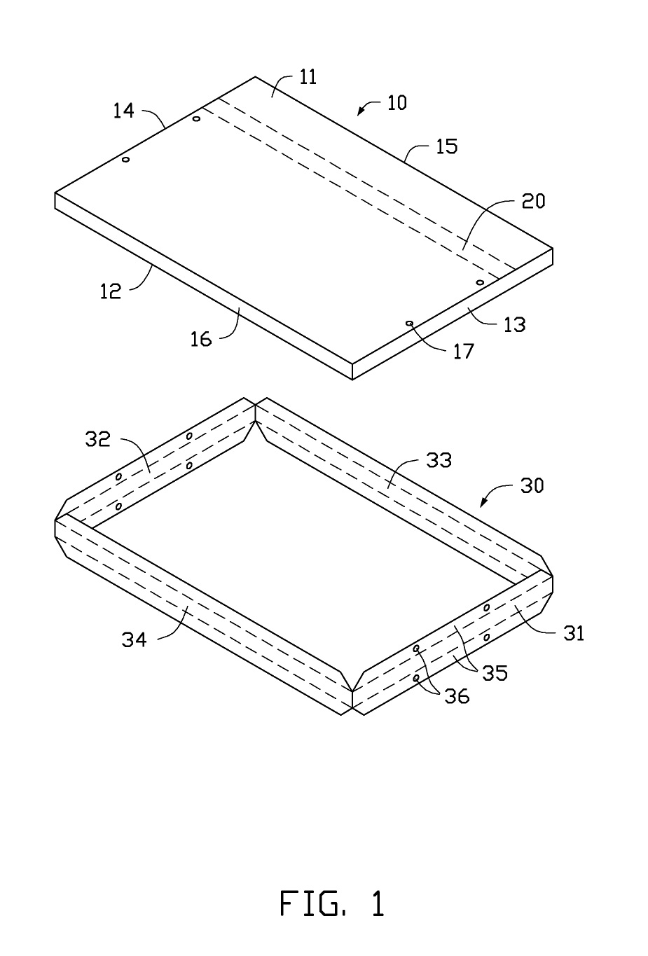

FIG. 1 shows one embodiment of a printed circuit board assembly. The printed circuit board assembly comprises a printed circuit board (PCB) 10 and a shielding structure 30 attached to the PCB 10.

The PCB 10 comprises a top surface 11, a bottom surface 12, a first side surface 13, a second side surface 14, a third side surface 15, and a fourth side surface 16. A signal transmission line 20 is laid in the top surface 11 adjacent to the third side surface 15. Four through holes 17 are defined in the PCB 10. Two of the four through holes 17 are adjacent to the first side surface 13, and the other two through holes 17 are adjacent to the second side surface 14.

A shielding structure 30 is attached to the PCB 10 and comprises a first shielding piece 31, a second shielding piece 32, a third shielding piece 33, and a fourth shielding piece 34 connected end-to-end. The first shielding piece 31, the second shielding piece 32, the third shielding piece 33, and the fourth shielding piece 34 securely contact the first side surface 13, the second side surface 14, the third side surface 15, and the fourth side surface 16, respectively. A flange 35 extends from an upper edge and a lower edge of each of the first shielding piece 31, the second shielding piece 32, the third shielding piece 33, and the fourth shielding piece 34. Two mounting holes 36 are defined in each top flange 35 and each bottom flange of the first shielding piece 31 and the second shielding piece 32. In one embodiment, the flanges 35 are ladder-shaped, and a height of each flange 35 and each bottom flange is about 10 mil to about 20 mil.

The top flanges 35 and the bottom flanges closely contact the top surface 11 and the bottom surface 12. Thus, the top flanges 35, the bottom flanges, the first shielding piece 31, the second shielding piece 32, the third shielding piece 33, and the fourth shielding piece 34 cooperatively surround edges of the PCB 10. Each mounting hole 36 is aligned with a corresponding through hole 17, and a fastener (not shown) is received through each through hole 17 and each mounting hole 36 to fix the shielding structure 30 to the PCB 10. A diameter of each through hole 17 is substantially equal to a diameter of each mounting hole 36. A length of the first shielding piece 31 and a length of the second shielding piece 32 are slightly greater than a width of the PCB 10. A length of the third shielding piece 33 and a length of the fourth shielding piece 34 are slightly greater than a length of the PCB 10. Widths of the first shielding piece 31, the second shielding piece 32, the third shielding piece 33, and the fourth shielding piece 34 are substantially equal to a thickness of the PCB 10. The shielding structure 30 can be made of copper or aluminum, but can be made of other suitable materials.

Using a software application called Computer Simulation Technology (CST) to simulate an EMI value of the PCB 10, the following test results of one embodiment were obtained and are shown below. For the simulated conditions, the length of the PCB 10 is 5000 mil, the width of the PCB 10 is 3000 mil, and the thickness of the PCB10 is 54.2 mil. A distance between the signal transmission line 20 and the third side surface 15 is 10 mil. A length of the signal transmission line 20 is 4990 mil. A width of the signal transmission line 20 is 5 mil. The simulation according to the simulated conditions shows that when a frequency of high-speed differential signals transmitted in the signal transmission line 20 increases from 0.2 GHZ to 10 GHZ, the corresponding EMI value for each frequency value is indicated in the table below:

| | EMI value of PCBs without | EMI value of PCBs with |
|---|---|---|
| Frequency (GHZ) | shielding structure (V/M) | shielding structure (V/M) |
| 0.2 | 0.00843 | 0.00433 |
| 0.4 | 0.0269 | 0.0135 |
| 0.6 | 0.0807 | 0.0387 |
| 0.8 | 0.114 | 0.0547 |
| 1 | 0.074 | 0.0358 |
| 2 | 0.168 | 0.0764 |
| 3 | 0.152 | 0.069 |
| 4 | 0.229 | 0.138 |
| 5 | 0.218 | 0.112 |
| 6 | 0.24 | 0.149 |
| 7 | 0.366 | 0.156 |
| 8 | 0.278 | 0.152 |
| 9 | 0.471 | 0.296 |
| 10 | 0.351 | 0.219 |

The EMI values of the PCB 10 are represented by electrical field strength per meter (V/M). According to the table, the EMI values of the PCB 10 using the shielding structure 30 are significantly reduced. Thus, an edge effect of the signal transmission line 20 is also reduced.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A printed circuit board (PCB) assembly, comprising:
a PCB comprising a top surface, a bottom surface, a first side surface, a second side surface, a third side surface and a fourth side surface, and a signal transmission line laid on the top surface; and
a shielding structure attached to the PCB; and the shielding structure contacting with the first side surface, the second side surface, the third side surface, the fourth side surface, and edges of the top surface, and the bottom surface of PCB, for shielding EMI from the signal transmission line when the signal transmission line transmitting high-speed differential signals.

2. The PCB assembly of claim 1, wherein the shielding structure comprises a first shielding piece, a second shielding piece, a third shielding piece and a fourth shielding piece, which are connected one by one; and the first shielding piece, the second shielding piece, the third shielding piece and the fourth shielding piece closely contact with the first side surface, the second side surface, the third side surface and the fourth side surface.

3. The PCB assembly of claim 2, wherein the shielding structure further comprises a flange extended from each of an upper edge and a lower edge of each of the first shielding piece, the second shielding piece, the third shielding piece and the fourth shielding piece; and the flanges contact with the edges of the top surface and the bottom surface.

4. The PCB assembly of claim 3, wherein two mounting holes are defined in each flange of the first shielding piece and the second shielding piece; four through holes are defined the PCB; and a fastener passes through each mounting hole and each through hole to fix the shielding structure to the PCB.

5. The PCB assembly of claim 3, wherein the flanges are trapezoid.

6. The PCB assembly of claim 3, wherein a height of the flanges is about from 10 mil to 20 mil.

7. The PCB assembly of claim 3, wherein a length of the first shielding piece and a length of the second shielding piece are slightly greater than a width of the PCB; and a length of the third shielding piece and a length of the fourth shielding piece are slightly greater than a length of the PCB.

8. The PCB assembly of claim 3, wherein a width of each of the first shielding piece, the second shielding piece, the third shielding piece and the fourth shielding piece are equal to a thickness of the PCB.

9. The PCB assembly of claim 1, wherein the shielding structure is made of copper.

10. The PCB assembly of claim 1, wherein the shielding structure is made of aluminum.

11. A printed circuit board (PCB) assembly, comprising:
a PCB comprising a top surface, and signal transmission line laid in the top surface; and
a shielding structure attached to the PCB and surrounding edges of the PCB configured to shield EMI in the signal transmission line when transmitting high-speed differential signals.

12. The PCB assembly of claim 11, wherein the PCB further comprising a bottom surface, a first side surface, a second side surface, a third side surface and a fourth side surface; the shielding structure comprises a first shielding piece, a second shielding piece, a third shielding piece and a fourth shielding piece connected one by one; the first shielding piece, the second shielding piece, the third shielding piece and the fourth shielding piece closely contact with the first side surface, the second side surface, the third side surface and the fourth side surface.

13. The PCB assembly of claim 12, wherein the shielding structure further comprises a flange extended from each of an upper edge and a lower edge of each of the first shielding piece, the second shielding piece, the third shielding piece and the fourth shielding piece; and the flanges closely contact with the edges of the top surface and the bottom surface.

14. The PCB assembly of claim 13, wherein two mounting holes are defined in each flange of the first shielding piece and the second shielding piece; four through holes are defined the PCB; and a fastener passes through each mounting hole and each through hole to fix the shielding structure on the PCB.

15. The PCB assembly of claim 13, where the flanges are trapezoid.

16. The PCB assembly of claim 13, wherein a height of the flanges is about from 10 mil to 20 mil.

17. The PCB assembly of claim 13, wherein a length of the first shielding piece and a length of the second shielding piece are slightly greater than a width of the PCB; and a length of the third shielding piece and a length of the fourth shielding piece are slightly greater than a length of the PCB.

18. The PCB assembly of claim 13, wherein a width of each of the first shielding piece, the second shielding piece, the third shielding piece and the fourth shielding piece are equal to a thickness of the PCB.

19. The PCB assembly of claim 11, wherein the shielding structure is made of copper.

20. The PCB assembly of claim 11, wherein the shielding structure is made of aluminum.
